(19) United States
(12) Patent Application Publication
(10) Pub. No.: US 2024/0215381 A1
(43) Pub. Date: Jun. 27, 2024

(54) DISPLAY DEVICE

(71) Applicant: Japan Display Inc., Tokyo (JP)

(72) Inventors: Hayata AOKI, Tokyo (JP); Jun NITTA, Tokyo (JP); Marina MOCHIZUKI, Tokyo (JP)

(73) Assignee: Japan Display Inc., Tokyo (JP)

(21) Appl. No.: 18/395,906

(22) Filed: Dec. 26, 2023

(30) Foreign Application Priority Data
Dec. 26, 2022 (JP) 2022-208330

(51) Int. Cl. H10K 59/80; H10K 59/122

(52) U.S. Cl. CPC H10K 59/80517; H10K 59/122; H10K 59/80523; H10K 59/80524; H10K 59/873

(57) ABSTRACT

According to one embodiment, a display device includes a plurality of pixels and a bank provided between each adjacent pair of the plurality of pixels, and each of the plurality of pixels includes, on a base, a cathode, an organic EL layer provided on the cathode, a protective layer provided to cover a side surface of the organic EL layer, and an anode provided on the protective layer and in an aperture of the bank, so as to be in contact with the organic EL layer.

### CROSS-REFERENCE TO RELATED APPLICATIONS

This application is based upon and claims the benefit of priority from Japanese Patent Application No. 2022-208330, filed Dec. 26, 2022, the entire contents of which are incorporated herein by reference.

### FIELD

Embodiments described herein relate generally to a display device.

### BACKGROUND

Organic electroluminescent (organic EL) display devices have been developed, which generate light emission by utilizing energy produced at the time of recombination between holes injected from the anode and electrons injected from the cathode.

### BRIEF DESCRIPTION OF THE DRAWINGS

FIG. 1 is an overall perspective view showing a display device of an embodiment.

FIG. 2 is a partial plan view schematically showing a configuration example of the display device.

FIG. 3 is a cross-sectional view of the display device taken along line A1-A2 shown in FIG. 2.

FIG. 4 is a cross-sectional view schematically showing a configuration example of the embodiment.

FIG. 5 is a cross-sectional view schematically showing a configuration example of the embodiment.

FIG. 6 is a cross-sectional view illustrating a process in a method of manufacturing the display device of the embodiment.

FIG. 7 is a cross-sectional view illustrating the method of manufacturing the display device of the embodiment.

FIG. 8 is a cross-sectional view illustrating a process in the method of manufacturing the display device of the embodiment.

FIG. 9 is a cross-sectional view illustrating a process in the method of manufacturing the display device of the embodiment.

FIG. 10 is a cross-sectional view illustrating a process in the method of manufacturing the display device of the embodiment.

FIG. 11 is a cross-sectional view illustrating a process in the method of manufacturing the display device of the embodiment.

FIG. 12 is a cross-sectional view illustrating a process in the method of manufacturing the display device of the embodiment.

FIG. 13 is a cross-sectional view illustrating a process in the method of manufacturing the display device of the embodiment.

FIG. 14 is a cross-sectional view illustrating a process in the method of manufacturing the display device of the embodiment.

FIG. 15 is a cross-sectional view illustrating a process in the method of manufacturing the display device of the embodiment.

FIG. 16 is a cross-sectional view illustrating a process in the method of manufacturing the display device of the embodiment.

FIG. 17 is a cross-sectional view illustrating a process in the method of manufacturing the display device of the embodiment.

FIG. 18 is a cross-sectional view illustrating a process in the method of manufacturing the display device of the embodiment.

FIG. 19 is a cross-sectional view illustrating a process in the method of manufacturing the display device of the embodiment.

FIG. 20 is a cross-sectional view illustrating a process in the method of manufacturing the display device of the embodiment.

FIG. 21 is a cross-sectional view illustrating a process in the method of manufacturing the display device of the embodiment.

FIG. 22 is a cross-sectional view illustrating a process in a method of manufacturing a display device of a comparative example.

FIG. 23 is a cross-sectional view illustrating a process in the method of manufacturing a display device of the comparative example.

FIG. 24 is a cross-sectional view illustrating a process in the method of manufacturing a display device of the comparative example.

### DETAILED DESCRIPTION

In general, according to one embodiment, a display device comprises
a plurality of pixels; and
a bank provided between each adjacent pair of the plurality of pixels,
each of the plurality of pixels comprising, on a base:
a cathode,
an organic EL layer provided on the cathode,
a protective layer provided to cover a side surface of the organic EL layer, and
an anode provided on the protective layer and in an aperture of the bank, so as to be in contact with the organic EL layer.

An object of this embodiment is to provide a display device with improved image quality.

Embodiments will be described hereinafter with reference to the accompanying drawings. Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

The embodiments described herein are not general ones, but rather embodiments that illustrate the same or corresponding special technical features of the invention. The following is a detailed description of one embodiment of a display device with reference to the drawings.

In this embodiment, a first direction X, a second direction Y and a third direction Z are orthogonal to each other, but may intersect at an angle other than 90 degrees. The direction toward the tip of the arrow in the third direction Z is defined as up or above, and the direction opposite to the direction toward the tip of the arrow in the third direction Z is defined as down or below. Note that the first direction X, the second direction Y and the third direction Z may as well be referred to as an X direction, a Y direction and a Z direction, respectively.

With such expressions as “the second member above the first member” and “the second member below the first member”, the second member may be in contact with the first member or may be located away from the first member. In the latter case, a third member may be interposed between the first member and the second member. On the other hand, with such expressions as “the second member on the first member” and “the second member beneath the first member”, the second member is in contact with the first member.

Further, it is assumed that there is an observation position to observe the optical control element on a tip side of the arrow in the third direction Z. Here, viewing from this observation position toward the X-Y plane defined by the first direction X and the second direction Y is referred to as plan view. Viewing a cross-section of the display device in the X-Z plane defined by the first direction X and the third direction Z or in the Y-Z plane defined by the second direction Y and the third direction Z is referred to as cross-sectional view.

### EMBODIMENTS

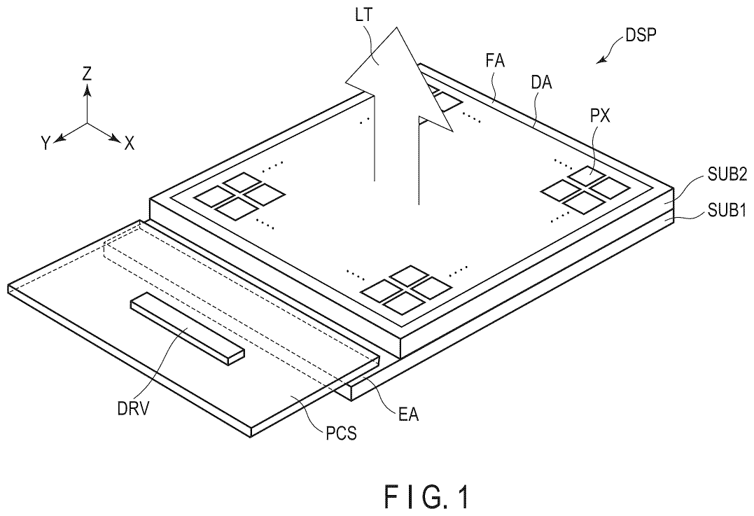

FIG. 1 is an overall perspective view of a display device of an embodiment. A display device DSP comprises a display area DA and a peripheral area FA provided around the display area DA on a substrate SUB1. The display device DSP includes a plurality of pixels PX arranged in the display area DA. In the display device DSP, light LT from the rear surface is transmitted to the front surface and vice versa.

On an upper surface of the display area DA, a substrate SUB2 is provided as a sealing member. The substrate SUB2 is fixed to the substrate SUB1 by a seal material (not shown) provided to surround the display area DA. The display area DA formed on the substrate SUB1 is sealed so as not to be exposed to the atmosphere by the substrate SUB2 as a sealing member and the sealing material.

An area EA in an end portion of the substrate SUB1 is located outside of the substrate SUB2. In the area EA, a wiring circuit board PCS is provided. On the wiring circuit board PCS, a drive element DRV that outputs video signals and drive signals is provided. Signals from the drive element DRV are input to the pixels PX in the display area DA via the wiring circuit board PCS. Based on the video signals and various control signals, the pixels PX emits light.

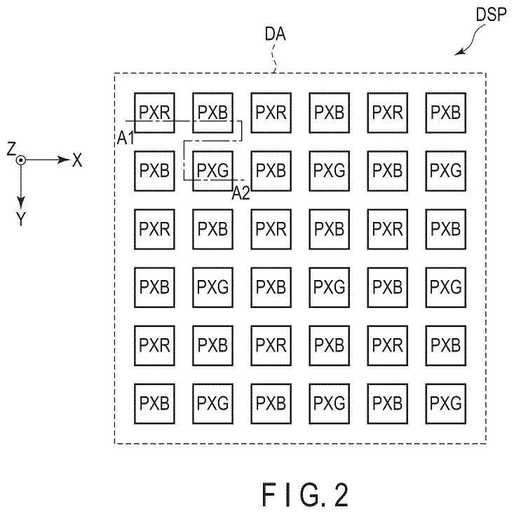

FIG. 2 is a partial plan view schematically showing a configuration example of the display device. The plurality of pixels PX includes pixels PXR which emit red color, pixels PXG which emit green color and pixels PXB which emit blue color. The pixels PXR, PXG and PXB may as well be referred to as a first pixel, a second pixel and a third pixel, respectively. Each pixel PXR is disposed next to respective pixels PXB along the first direction X and the second direction Y. Each pixel PXG is disposed next to respective pixels PXB along the first direction X and the second direction Y. Each pixel PXB is disposed next to a respective pixel PXR along the first direction and next to a respective pixel PXG along the second direction Y.

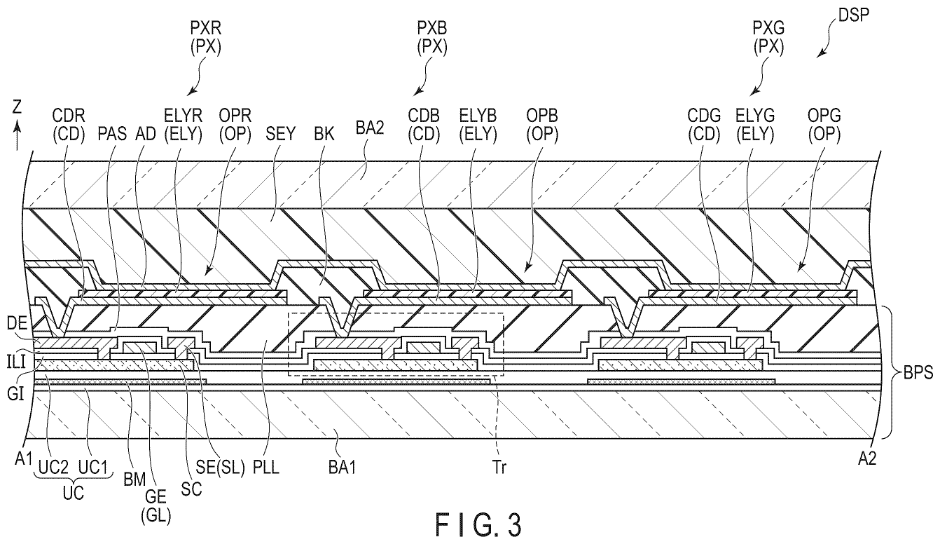

FIG. 3 is a diagram showing a cross-sectional view of the display device taken along line A1-A2 shown in FIG. 2.

A base BA1 is, for example, glass or a base material made of a resin material. For example, acrylic, polyimide, polyethylene terephthalate, polyethylene naphthalate or the like may be used as the resin material, and may be formed from a single layer or a stacked body of multiple layers of any of these.

An insulating layer UC1 is provided on the base BA1. The insulating layer UC1 is formed from, for example, a single layer of a silicon oxide film or silicon nitride film or a stacked body of these layers.

On the insulating layer UC1, a light-shielding layer BM may as well be provided to overlap a transistor Tr. The light-shielding layer BM suppresses changes in transistor characteristics, which may be caused by light penetration or the like from the rear surface of the channel of the transistor Tr. When the light-shielding layer BM is formed of a conductive layer, it is also possible to impart a back-gate effect to the transistor Tr by providing a predetermined potential.

An insulating layer UC2 is provided to cover the insulating layer UC1 and the light-shielding layer BM. For the insulating layer UC2, a material similar to that of the insulating layer UC1 can be used. The insulating layer UC2 may as well be made of a material different from that of the insulating layer UC1. For example, silicon oxide can be used for the insulating layer UC1, whereas silicon nitride for the insulating layer UC2. The insulating layers UC1 and UC2 together may be referred to as insulating layer UC.

The transistor Tr is provided on the insulating layer UC. The transistor Tr includes a semiconductor layer SC, an insulating layer GI, a gate electrode GE (a scanning line GL), an insulating layer ILI, a source electrode SE (a signal line SL) and a drain electrode DE.

As the semiconductor layer SC, amorphous silicon, polysilicon or an oxide semiconductor is used.

As the insulating layer GI, for example, silicon oxide or silicon nitride is provided in a single layer or in a stacked body of these layers.

For example, a molybdenum-tungsten alloy (MoW) is used as the gate electrode GE. The gate electrode GE may be formed to be integrated with the scanning line GL.

The insulating layer ILI is provided to cover the semiconductor layer SC and the gate electrode GE. The insulating layer ILI is formed, for example, by a single layer of a silicon oxide layer or silicon nitride layer or a stacked body of these layers.

On the insulating layer ILI, the source electrode SE and the drain electrode DE are provided. The source electrode SE and drain electrode DE are connected to the source region and drain region of the semiconductor layer SC, respectively, via contact holes made in the insulating layer ILI and the insulating layer GI. The source electrode SE may as well be formed to be integrated with the signal line SL.

An insulating layer PAS is provided to cover the source electrode SE, the drain electrode DE and the insulating layer ILI. Further, an insulating layer PLL is provided to cover the insulating layer PAS.

The insulating layer PAS is formed using an inorganic insulating material. The inorganic insulating material is, for example, a single layer of silicon oxide or silicon nitride or a stacked body of these. The insulating layer PLL is formed using an organic insulating material. The organic insulating material is, for example, an organic material such as photosensitive acrylic, polyimide or the like. With the insulating layer PLL thus provided, steps caused by the transistor Tr can be planarized.

On the insulating layer PLL, the cathode CD is provided. The cathode CD is connected to the drain electrode DE via contact holes made in the insulating layers PAS and PLL. The cathode provided in the pixel PXR is referred to as a cathode CDR, the cathode provided in the pixel PXB is referred to as a cathode CDB, and the cathode provided in the pixel PXG is referred to as a cathode CDG. When it is not necessary to distinguish the cathode CDR, cathode CDG and cathode CDB from each other, they are simply referred to as cathodes CD.

The cathodes CD are each formed, for example, from a magnesium-silver alloy (MgAg) film, a single layer film of silver (Ag), a stacked layered film of silver (Ag) and a transparent conductive material or the like. As the transparent conductive material, for example, indium tin oxide (ITO) or indium zinc oxide (IZO) can be used.

In this embodiment, the configuration from the base BA1 to the insulating layer PLL is referred to as a backplane BPS.

A bank BK (which may as well be referred to as a projecting portion or rib) is provided between each adjacent pair of cathodes PE. As the material of the bank BK, an organic material similar to the material of the insulating layer PLL is used. The bank BK is opened to expose a part of the respective cathode CD.

An aperture made in the pixel PXR is referred to as an aperture OPR, an aperture in the pixel PXB is referred to as an aperture OPB, and an aperture in the pixel PXG is referred to as an aperture OPG. When it is not necessary to distinguish the aperture OPR, aperture OPB and aperture OPG from each other, they are simply referred to as apertures OP.

Note here that it is preferable that an end portion of the apertures OP should be gently tapered in cross-sectional view. If the end portion of the aperture OP has a steep shape, coverage defects will occur in an organic EL layer ELY that is to be formed later.

The organic EL layer ELY is provided between each adjacent pair of banks BK so as to overlap the respective cathode CD. Although the details will be provided later, the organic EL layer ELY includes an electron transport layer ETY, a light emitting layer EML, a hole transport layer HTL and a hole injection layer HIL. When necessary, the organic EL layer ELY may further include an electron injection layer, an electron blocking layer and a hole blocking layer.

The organic EL layer provided in the pixel PXR is referred to as an organic EL layer ELYR, the organic EL layer in the pixel PXB is referred to as an organic EL layer ELYB, and the organic EL layer in the pixel PXG is referred to as an organic EL layer ELYG. When it is not necessary to distinguish the organic EL layer ELYR, organic EL layer ELYB and organic EL layer ELYG from each other, they are simply referred to as an organic EL layer ELY.

An anode AD is provided on the organic EL layer ELY. The anode AD is formed, for example, from a three-layer stacked structure of indium zinc oxide (IZO), silver (Ag) and indium zinc oxide (IZO), or a two-layer stacked structure of molybdenum tungsten alloy (MoW) and indium tin oxide (ITO). Alternatively, the anode AD may as well be formed using aluminum (Al) or an aluminum (Al) alloy. In this case, the anode AD has a three-layer stacked structure in which a sufficiently thin layer of a barrier metal such as titanium (Ti) is stacked on aluminum (Al) or aluminum alloy and them, indium tin oxide (ITO) is further stacked thereon. Examples of the material alloyed with aluminum include neodymium (Nd), titanium (Ti), tantalum (Ta) and lanthanum (La).

An insulating layer SEY is provided to cover the anode AD. The insulating layer SEY has a function of preventing moisture from entering the organic EL layer ELY from the outside. As the insulating layer SEY, a material having a high gas barrier property is preferable. As the insulating layer SEY, for example, a layer obtained by sandwiching an organic insulating layer between two inorganic insulating layers containing nitrogen, can be used. Examples of the material for the organic insulating layer are acrylic resin, epoxy resin and polyimide resin. Examples of the material for the inorganic insulating layer containing nitrogen are silicon nitride and aluminum nitride.

A base BA2 is provided on the insulating layer SEY. The base BA2 is formed of a material similar to that of the base BA1. Between the base BA2 and the insulating layer SEY, a translucent inorganic insulating layer or a translucent organic insulating layer may as well be provided. The organic insulating layer may as well have the function of adhering the insulating layer SEY and the base BA2 together.

The light emission generated in the organic EL layer ELY is extracted upward via the anode AD. In other words, the display device DSP of this embodiment has a top emission structure.

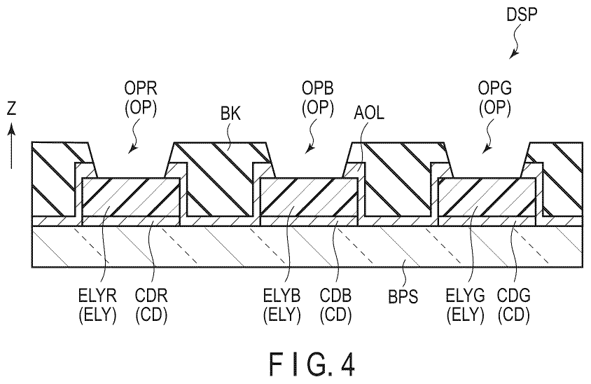

FIG. 4 is a cross-sectional view schematically showing a configuration example of the embodiment. In the display device DSP shown in FIG. 4, only the configuration near the organic EL layer ELY is illustrated. In FIG. 4, the cathode CD (a cathode CDR, a cathode CDG and a cathode CDB) is provided on the backplane BPS.

On the cathode CD, the organic EL layer ELY is provided. On the cathode CDR, the organic EL layer ELYR is provided. On the cathode CDB, the organic EL layer ELYB is provided. On the cathode CDG, the organic EL layer ELYG is provided.

A protective layer AOL is provided so as to over respective side surfaces of the cathode CDR, cathode CDG, cathode CDB, organic EL layer ELYR, organic EL layer ELYG and organic EL layer ELYB. The protective layer AOL is formed of, for example, aluminum oxide (AlOx).

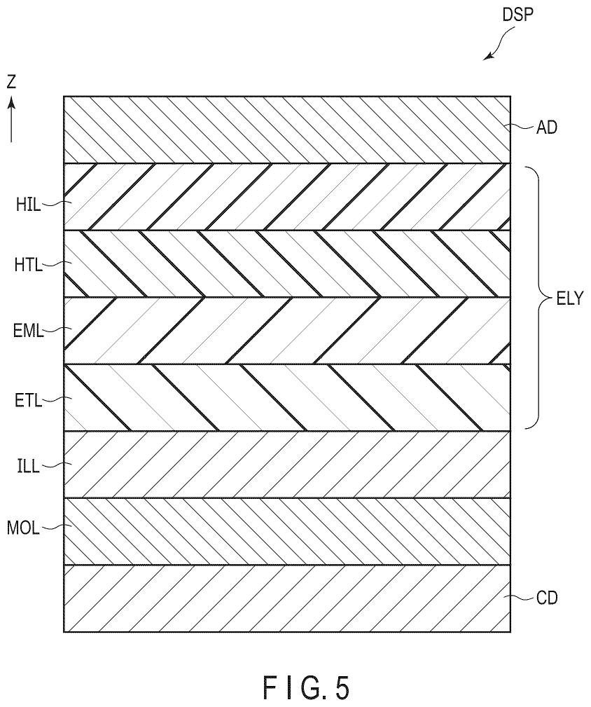

Although not shown in FIG. 4, a metal oxide layer and an intermediate layer are provided between the cathode CD and the organic EL layer ELY, which will be described in detail later with reference to FIG. 5.

The bank BK is provided on the protective layer AOL and between each adjacent pair of organic EL layers ELY. The apertures OP (apertures OPR, apertures OPB, and apertures OPG) are each provided between each respective adjacent pair of banks BK. Although not shown in FIG. 4, the anode AD is provided to cover the bank BK, the organic EL layer ELY and the protective layer AOL.

FIG. 5 is a cross-sectional view schematically showing a configuration example of the embodiment. FIG. 5 is a partially enlarged view of the illustration of FIG. 4. As shown in FIG. 5, between the cathode CD and the anode AD, a metal oxide layer MOL, an intermediate layer ILL and an organic EL layer ELY are provided along the third direction Z. The organic EL layer ELY includes an electron transport layer ETL, a light emitting layer EML, a hole transport layer HTL and a hole injection layer HIL, which are stacked one on another along the third direction Z.

The metal oxide layer MOL is a conductive layer having translucency, which is made, for example, of zinc oxide (ZnO).

The intermediate layer ILL is formed of an amine derivative, for example, polyethyleneimine (PEI). With intermediate layer ILL of an amine derivative thus formed, electron injection is increased. Therefore, the intermediate layer ILL can be referred to as an electron injection layer.

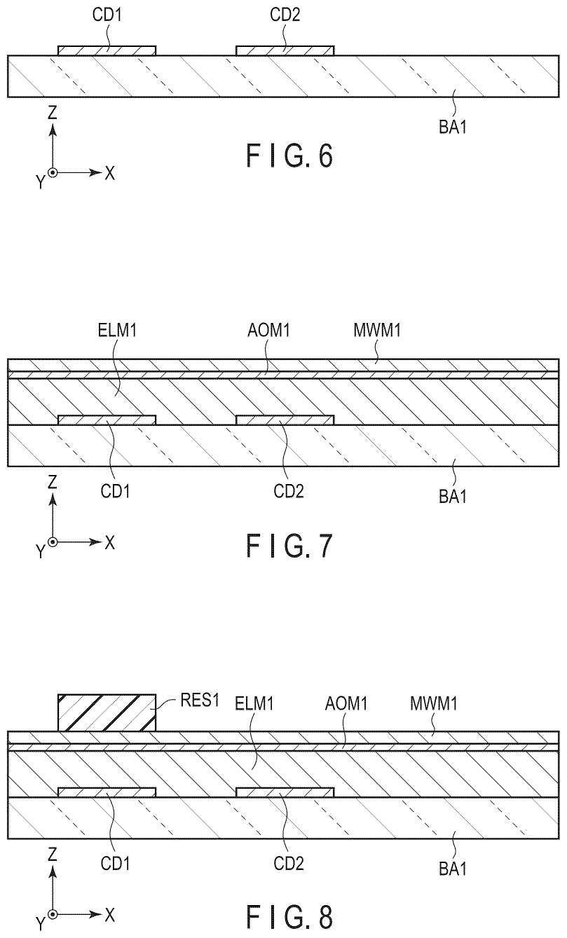

FIGS. 6 through 21 are cross-sectional views showing a method of manufacturing the display device of the embodiment. In FIGS. 6 to 21, the first pixel, which is one of the pixel PXR, pixel PXG and pixel PXB, is designated as a pixel PX1, and the second pixel, which is another one, is designated as a pixel PX2. In FIGS. 6 to 21, the first pixel (pixel PX1) and the second pixel (pixel PX2) are formed in this order. Although not shown, a third pixel, which is the other one of the pixel PXR, pixel PXG and pixel PXB (let us referred to it as a pixel PX3 for the sake of description), is formed in a manner similar to that of the first pixel and the second pixel. Further, in FIGS. 6 to 21, the base BA1 represents the backplane BPS.

First, a cathode CD1 and a cathode CD2 are formed on base BA1 (see FIG. 6). The cathode CD1 is the cathode of the pixel PX1, and the cathode CD2 is the cathode of the pixel PX2. Although not illustrated in FIG. 6, an intermediate layer and a metal oxide layer are provided on each of the cathode CD1 and the cathode CD2, as described with reference to FIG. 5.

An organic EL layer ELM1, a sacrificial layer AOM1 and a sacrificial layer MWM1 are formed to cover the base BA1, the cathode CD1 and the cathode CD2 and further the intermediate layer and the metal oxide layer described above (see FIG. 7). The organic EL layer ELM1 is an organic EL layer which corresponds to the pixel PX1.

The sacrificial layer AOM1 is formed, for example, of aluminum oxide (AlOx). Aluminum oxide can be deposited by the atomic layer deposition (ALD) method.

The sacrificial layer MWM1 is formed, for example, of molybdenum-tungsten (MoW). Molybdenum-tungsten can be deposited by the sputtering method.

A resist mask RES1 is formed on the sacrificial layer MWM1 so as to oppose the cathode CD1 (see FIG. 8). No resist mask is formed on the cathode CD2.

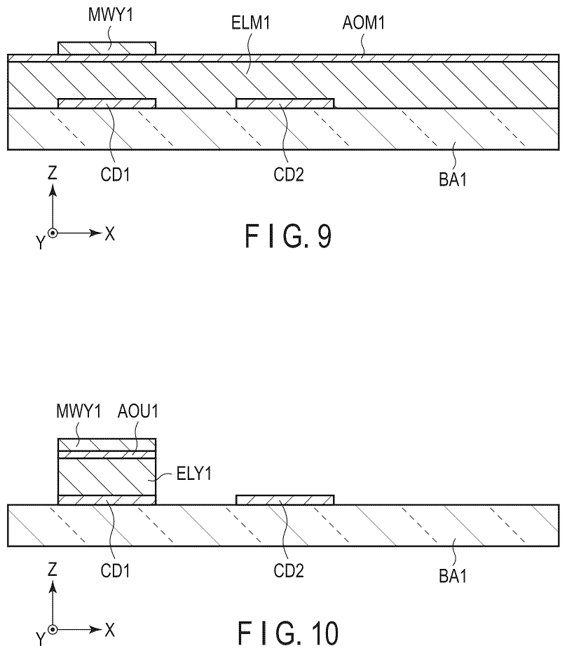

Using the resist mask RES1, the sacrificial layer MWM1 is partially removed by etching. As a result, the sacrificial layer MWY1 is formed in an island shape so as to oppose the cathode CD1 and interpose the sacrificial layer AOM1 therebetween (see FIG. 9).

Using the island-shaped sacrificial layer MWY1 as a mask, the sacrificial layer AOM1 and the organic EL layer ELM1 are partially removed by etching. As a result, the organic EL layer ELY1 and an upper layer AOU1 of the sacrificial layer are formed in an island shape between the cathode CD1 and the sacrificial layer MWY1 (see FIG. 10). Here, the sacrificial layer AOM1 and the organic EL layer ELM1 on the cathode CD2 are removed.

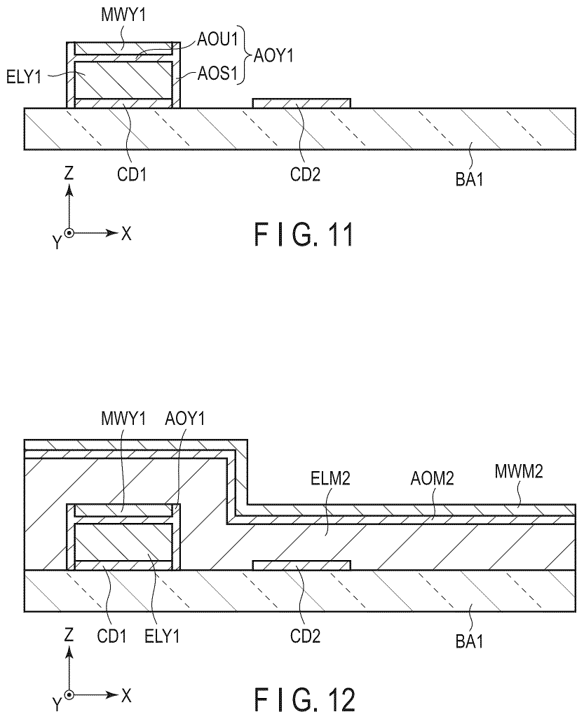

A side wall AOS1 is formed in contact with the side surfaces of the cathode CD1, the organic EL layer ELY1, the upper layer AOU1 and the sacrificial layer MWY1. The side wall AOS1 is formed of the same material as that of the sacrificial layer AOM1. The upper layer AOU1 and the side wall AOS1 are together referred to as a sacrificial layer AOY1 (see FIG. 11).

In order to form the side wall AOS1, first, a material film that gives rise to the side wall AOS1 is formed so as to cover the stacked boy of the organic EL layer ELY1, the upper layer AOU1 and the sacrificial layer MWY1. After that, the material film is anisotropically etched to leave only the region in contact with the side surface of the stacked body and remove the rest of the part.

An organic EL layer ELM2, a sacrificial layer AOM2 and a sacrificial layer MWM2 are formed to cover the base BA1, the sacrificial layer AOY1, the sacrificial layer MWY1 and the cathode CD2 (see FIG. 12). The organic EL layer ELM2 is an organic EL layer which corresponds to the pixel PX2.

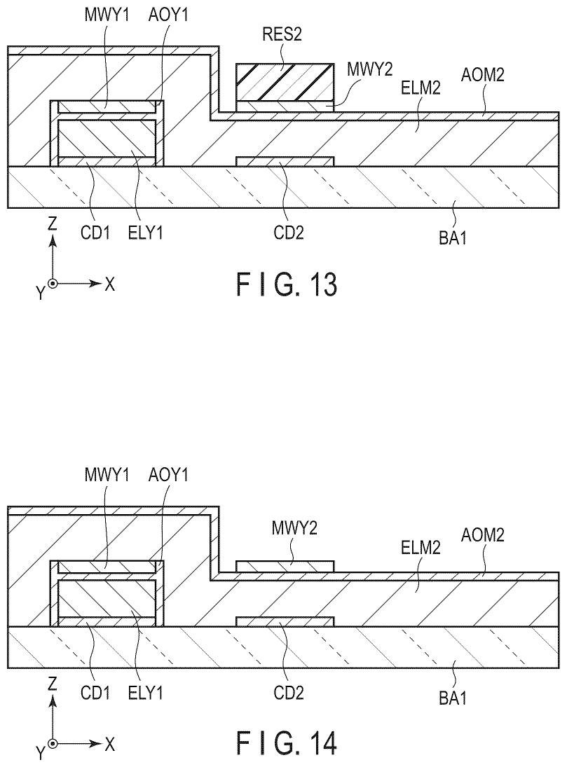

A resist mask RES2 is formed on the sacrificial layer MWM2, so as to oppose the cathode CD2. Using the resist mask RES2, the sacrificial layer MWM2 is partially removed by etching. As a result, the sacrificial layer MWY2 is formed in an island shape, so as to oppose the cathode CD2 and interpose the sacrificial layer AOM2 therebetween (see FIG. 13). Then, the resist mask RES2 is removed (see FIG. 14).

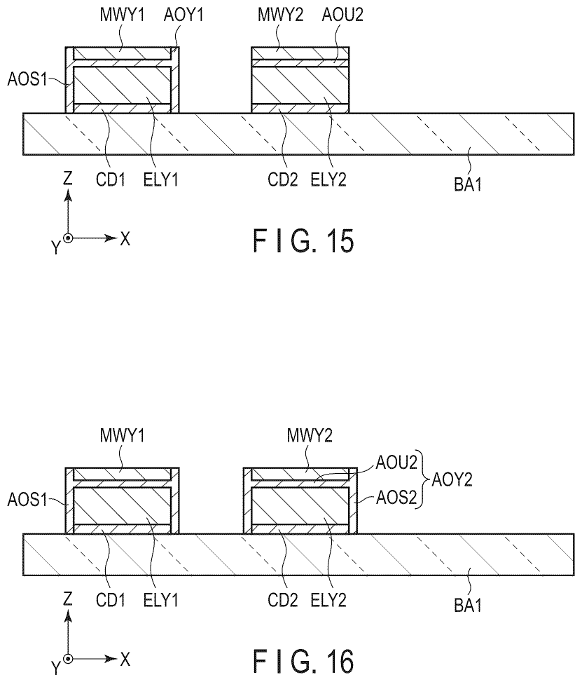

Using the island-shaped sacrificial layer MWY2 as a mask, the sacrificial layer AOM2 and the organic EL layer ELM2 are partially removed by etching. As a result, between the cathode CD2 and the sacrificial layer MWY2, the organic EL layer ELY2 and an upper layer AOU2 of the sacrificial layer are formed in an island shape (see FIG. 15).

A side wall AOS2 is formed in contact with respective side surfaces of the cathode CD2, the organic EL layer ELY2, the upper layer AOU2 and the sacrificial layer MWY2. The side wall AOS2 is formed of the same material as that of the sacrificial layer AOM2. The upper layer AOU2 and the side wall AOS2 are together referred to as a sacrificial layer AOY2 (see FIG. 16).

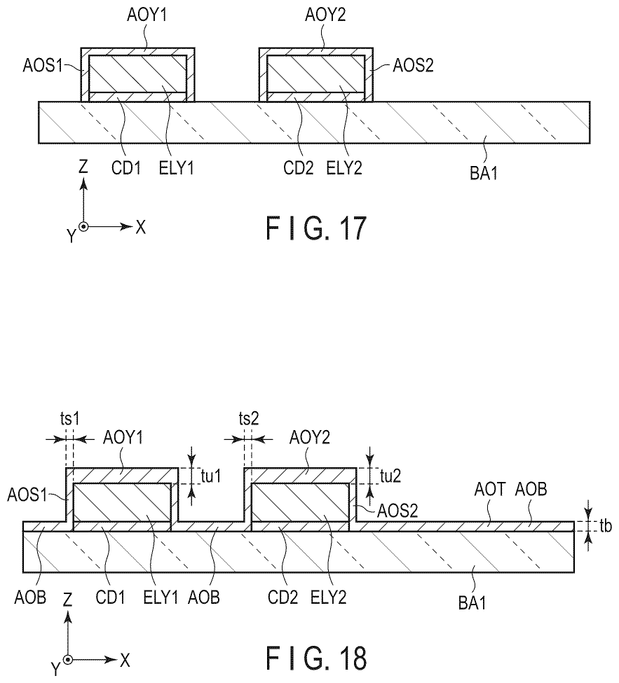

Then, the sacrificial layer MWY1 and the sacrificial layer MWY2 are removed (see FIG. 17). At this time, the upper layer AOU1 of the sacrificial layer AOY1 and the upper layer AOU2 of the sacrificial layer AOY2 are planarized.

After that, a sacrificial layer is formed to cover the upper layer AOU1 and the side wall AOS1 of the sacrificial layer AOY1 and the upper layer AOU2 and the side wall AOS2 of the sacrificial layer AOY2, from the same material as that of these sacrificial layers, namely, the same material as that of the sacrificial layer AOM1 and the sacrificial layer AOM2. As a result, the upper layer AOU1, the side wall AOS1, the upper layer AOU2, the side wall AOS2 and the newly formed sacrificial layer are all integrated to form a sacrificial layer AOT (see FIG. 18). With this configuration, a thickness tu1 of the upper layer AOU1 and a thickness tu2 of the upper layer AOU2 are greater than a thickness ts1 of the side wall AOS1 and a thickness ts2 of the side wall AOS2, respectively. The region of the sacrificial layer AOT, which is in contact with the base BA1 is referred to as a region AOB. A thickness tb of the region AOB should be the same as the thickness ts1 and the thickness ts2.

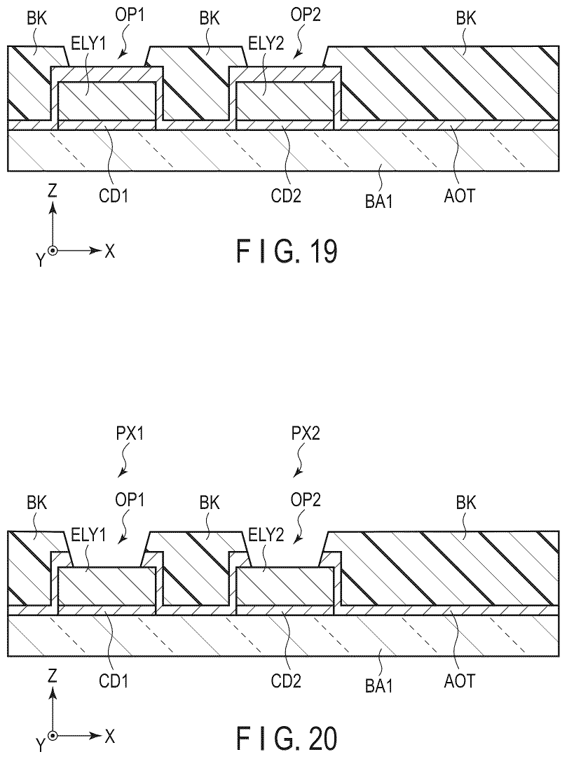

A bank BK is formed between the organic EL layer ELY1 and the organic EL layer ELY2 so as to be in contact with the sacrificial layer AOT. Note that the bank BK is not formed above each of the organic EL layer ELY1 and the organic EL layer ELY2. In other words, an aperture OP1 and an aperture OP2 are formed above the organic EL layer ELY1 and the organic EL layer ELY2, respectively (see FIG. 19).

Then, the sacrificial layer AOT located in the aperture OP1 and the aperture OP2 is removed. As a result, the organic EL layer ELY1 and the organic EL layer ELY2 are exposed in the aperture OP1 and the aperture OP2 formed in the bank BK and the sacrificial layer AOL, respectively (see FIG. 20).

The anode AD, the insulating layer INS and the insulating layer PCL are formed to cover the organic EL layer ELY1 and the organic EL layer ELY2, which are exposed, and the bank BK. On the insulating layer PCL, the base BA2 is provided.

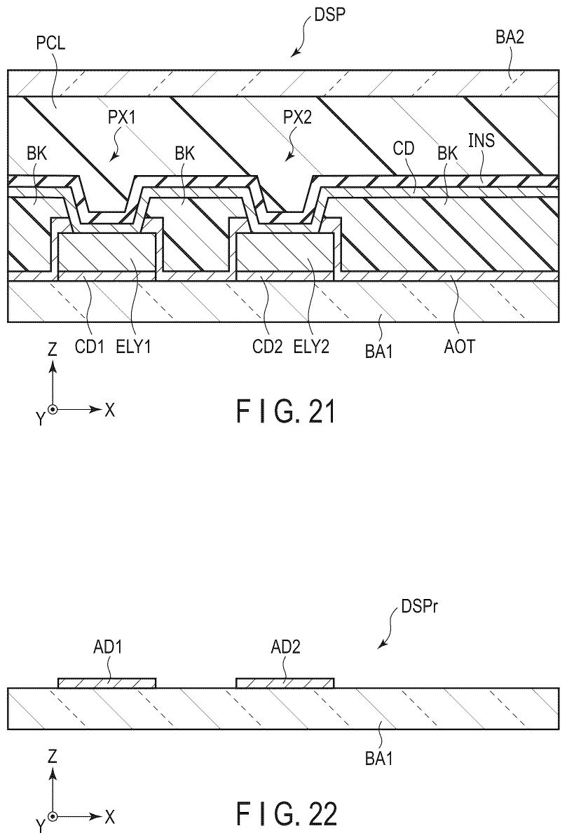

In the aperture OP1 and the aperture OP2, the anode AD is provided on the organic ELY1 and the organic ELY2, respectively. In other words, the anode AD is in contact with the organic EL layer ELY1 and the organic EL layer ELY2. With the above-described processing steps, the display device DSP of the embodiment is formed (see FIG. 21).

The insulating layer INS is formed, for example, of silicon nitride (SiN). The insulating layer INS prevents moisture from entering the organic EL layer from the outside. The insulating layer PCL is formed, for example, of a resin insulating material. The insulating layer PCL has the function of planarizing the surface. The base BA2 can be made of a material similar to that of the base BA1.

In order to form an anode and an organic EL layer of the pixel PX3, which is the third pixel, it suffices if the organic EL layer and the two sacrificial layers are formed so as to cover the anode of the pixel PX3 after the process shown in FIG. 16 is completed, as in the case shown in FIG. 12. As in the case shown in FIG. 16, after forming the side wall of the sacrificial layers of the pixel PX3, the process should only proceed to the step shown in FIG. 17.

The sacrificial layer AOT (the sacrificial layer AOY1, sacrificial layer AOY2, sacrificial layer AOS1, sacrificial layer AOS2 and sacrificial layer AOB) corresponds to the protective layer AOL shown in FIG. 4. The protective layer AOL (the sacrificial layer AOT) formed of aluminum oxide covers the side surface of the organic EL layer, thereby making it possible to protect the organic EL layer.

FIGS. 22 to 24 are cross-sectional views showing a method of manufacturing a display device of a comparative example. In order to manufacture a display device DSPr of the comparative example, first, an anode AD1 and an anode AD2 are formed on a base BA1 (see FIG. 22). The processing step shown in FIG. 22 corresponds to the step shown in FIG. 6.

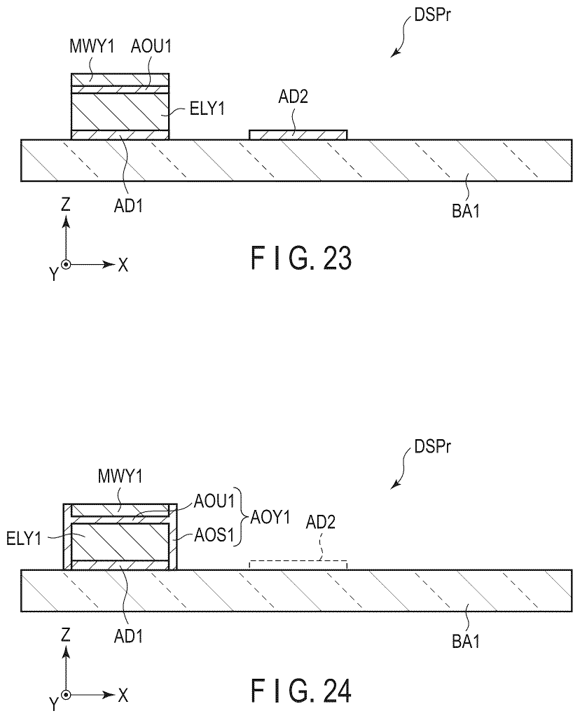

Through the processing steps shown in FIGS. 7 to 9, an organic EL layer ELY1 and an upper layer AOU1 of a sacrificial layer and a sacrificial layer MWY1 are formed on the anode AD1. On the anode AD2, the sacrificial layer is removed (see FIG. 23). The processing step shown in FIG. 23 corresponds to the step shown in FIG. 10.

Next, as in the case shown in FIG. 11, a side wall AOS1 is formed to be in contact with side surfaces of the anode AD1, the organic EL layer ELY1, the upper layer AOU1 and the sacrificial layer MWY1 (see FIG. 24). In a manner similar to that described above, a material film that gives rise to the side wall AOS1 is formed to cover the stacked body of the organic EL layer ELY1, the upper layer AOU1 and the sacrificial layer MWY1. After that, the material film is anisotropically etched to leave only the region in contact with the side surface of the stacked body and remove the rest of the part, thereby forming the side wall AOS1.

The material of the side wall AOS1 is the same material as that of the sacrificial layer AOM1, which is, for example, aluminum oxide (AlOx). On the other hand, the anode AD1 and the anode AD2 are formed, for example, from a three-layer stacked structure of indium zinc oxide (IZO), silver (Ag) and indium zinc oxide (IZO) or a two-layer structure of a molybdenum tungsten alloy (MoW) and indium tin oxide (ITO) as described above.

In other words, the side wall AOS1, as well as the anode AD1 and the anode AD2 are formed of materials containing metal oxides. When etching such metal oxides, it may be, in some cases, necessary to use an etchant that cannot obtain a selective ratio.

In this case, the anode AD2 may be removed together in the etching to form the side wall AOS1. If the anode is removed, the pixel thereof will not emit light. In such a display device, the display quality will deteriorate.

In the display device DSP of this embodiment, the anodes and cathodes are provided in opposite positions. With this configuration, the display device DSP of this embodiment can be manufactured without losing the anodes in the manufacturing process shown in FIGS. 6 to 21.

The cathode CD (a cathode CDR, a cathode CDG and a cathode CDB) is formed from a magnesium-silver alloy (MgAg) as described above. In the processing step shown in FIG. 10, the cathode CD is not etched by the etchant for the sacrificial layer AOM1 and the organic EL layer ELM1, which are formed of metal oxides. Therefore, the cathode CD is not lost. Therefore, such a phenomenon that some pixels do not emit light does not occur, and it is possible to prevent the deterioration in the display quality of the display device DSP.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a plurality of pixels; and
a bank provided between each adjacent pair of the plurality of pixels,
each of the plurality of pixels comprising, on a base:
a cathode,
an organic EL layer provided on the cathode,
a protective layer provided to cover a side surface of the organic EL layer, and
an anode provided on the protective layer and in an aperture of the bank, so as to be in contact with the organic EL layer.

2. The display device according to claim 1, wherein
the protective layer is formed of aluminum oxide.

3. The display device according to claim 1, wherein
the cathode is one of a magnesium-silver alloy film, a single layer film of silver and a stacked layered film of silver (Ag) and a transparent conductive material, and
the transparent conductive material is indium tin oxide or indium zinc oxide.

4. The display device according to claim 1, wherein
the anode is of a three-layer multilayer structure of indium zinc oxide, silver and indium zinc oxide, a two-layer stacked structure of molybdenum-tungsten alloy and indium tin oxide, or a three-layer stacked multilayer structure of aluminum alloy, titanium and indium tin oxide.
